(19) United States
(12) Patent Application Publication
(10) Pub. No.: US 2026/0007014 A1
(43) Pub. Date: Jan. 1, 2026

(54) DISPLAY DEVICE AND ELECTRONIC DEVICE INCLUDING THE SAME

(71) Applicant: Samsung Display Co., Ltd., Yongin-si (KR)

(72) Inventors: HEEJU WOO, Yongin-si (KR); KIYONG KIM, Yongin-si (KR); CHOLONG WON, Yongin-si (KR); HYUNGBIN CHO, Yongin-si (KR)

(21) Appl. No.: 19/065,935

(22) Filed: Feb. 27, 2025

(30) Foreign Application Priority Data
Jun. 27, 2024 (KR) 10-2024-0084486

(51) Int. Cl. H10K 59/131

(52) U.S. Cl. CPC H10K 59/131

(57) ABSTRACT

A display device includes: a base layer; a pixel; a signal line electrically connected to the pixel; and a signal pad connected to the signal line. The signal pad includes: a first conductive pattern connected to an end portion of the signal line; an insulating pattern on the first conductive pattern; a second conductive pattern contacting the first conductive pattern, and including a portion on a part of an upper surface of the insulating pattern; and a third conductive pattern on the first conductive pattern, and including a portion overlapping with the portion of the second conductive pattern. A partial area of the upper surface of the insulating pattern is exposed from the second conductive pattern and the third conductive pattern, and the end portion of the signal line is connected to the first conductive pattern through a first contact hole defined in a first group of insulating layers.

### CROSS-REFERENCE TO RELATED APPLICATION

The present application claims priority to and the benefit of Korean Patent Application No. 10-2024-0084486, filed on Jun. 27, 2024, in the Korean Intellectual Property Office, the entire disclosure of which is incorporated by reference herein.

### BACKGROUND

### 1. Field

Aspects of embodiments of the present disclosure relate to a display device including a pad area, and an electronic device including the display device.

### 2. Description of the Related Art

Various display devices used in multimedia devices, such as a television, a mobile phone, a tablet computer, a car navigation unit, a game machine, and the like, are being developed. The display devices may include a keyboard or a mouse as an input device. In addition, the display devices may include an input sensor, such as a touch panel, as an input device.

A display device includes a display area that is activated depending on an electrical signal. Through the display area, the display device may sense an input applied from the outside, and may display various images to provide information to a user.

The display device includes a display panel and a circuit board. The display panel may be connected to a main board through the circuit board. A driver chip may be mounted on the display panel.

The above information disclosed in this Background section is for enhancement of understanding of the background of the present disclosure, and therefore, it may contain information that does not constitute prior art.

### SUMMARY

Embodiments of the present disclosure may be directed to a display device in which a bonding reliability of signal pads may be improved, and an electronic device including the display device.

According to one or more embodiments of the present disclosure, a display device includes: a base layer; a pixel on the base layer; a signal line electrically connected to the pixel; a signal pad connected to the signal line; and a plurality of insulating layers on the base layer. The signal pad includes: a first conductive pattern connected to an end portion of the signal line; an insulating pattern on the first conductive pattern; a second conductive pattern contacting the first conductive pattern, the second conductive pattern including a portion on a part of an area of an upper surface of the insulating pattern; and a third conductive pattern on the first conductive pattern, the third conductive pattern including a portion overlapping with the portion of the second conductive pattern on the upper surface of the insulating pattern. A partial area of the upper surface of the insulating pattern is exposed from the second conductive pattern and the third conductive pattern. The plurality of insulating layers includes a first group of insulating layers between the end portion of the signal line and the first conductive pattern, and the end portion of the signal line and the first conductive pattern are connected to each other through a first contact hole defined in the first group of insulating layers.

In an embodiment, the third conductive pattern further includes a portion that does not overlap with the portion of the second conductive pattern on the upper surface of the insulating pattern.

In an embodiment, the end portion of the signal line may extend in a first direction in a plan view, a first area may be an area of the upper surface of the insulating pattern where the second conductive pattern and the third conductive pattern overlap with each other, a second area may be an area of the upper surface of the insulating pattern where the second conductive pattern is located and the third conductive pattern is not located, a third area may be an area of the upper surface of the insulating pattern where the third conductive pattern is located and the second conductive pattern is not located, and the second area and the third area may face each other in a second direction crossing the first direction.

In an embodiment, a fourth area may be the partial area of the upper surface of the insulating pattern that is exposed from the second conductive pattern and the third conductive pattern, and the fourth area may include a fourth-first area and a fourth-second area spaced from each other in the first direction.

In an embodiment, the insulating pattern may further include a first side surface and a second side surface opposite to each other in the first direction, and a third side surface and a fourth side surface opposite to each other in the second direction. The first side surface and the second side surface may be exposed from the second conductive pattern and the third conductive pattern.

In an embodiment, the third side surface may contact the second conductive pattern, and the fourth side surface may contact the third conductive pattern.

In an embodiment, the portion of the second conductive pattern may include a first edge, the portion of the third conductive pattern may include a second edge facing in a direction opposite to that of the first edge in the second direction, and the first edge and the second edge may overlap with each other on the upper surface of the insulating pattern.

In an embodiment, the first edge and the second edge may have a semicircular shape.

In an embodiment, the end portion of the signal line may extend in a first direction in a plan view. The insulating pattern may further include a first side surface and a second side surface opposite to each other in the first direction, and a third side surface and a fourth side surface opposite to each other in a second direction crossing the first direction. The second side surface may be exposed from the second conductive pattern, and the fourth side surface may be exposed from the third conductive pattern.

In an embodiment, the end portion of the signal line may extend in a first direction in a plan view. The insulating pattern may further include a first side surface and a second side surface opposite to each other in the first direction, and a third side surface and a fourth side surface opposite to each other in a second direction crossing the first direction. The first side surface and the fourth side surface may be exposed from the second conductive pattern, and the first side surface and the third side surface may be exposed from the third conductive pattern.

In an embodiment, the display device may further include: an electronic part electrically connected to the signal pad. The electronic part may include a bump electrically connected to the signal pad, and the second conductive pattern and the third conductive pattern located on the upper surface of the insulating pattern may contact the bump.

In an embodiment, the end portion of the signal line may extend in a first direction in a plan view, the first contact hole may include a plurality of first contact holes, the plurality of first contact holes may be located along the first direction, the insulating pattern may include a plurality of insulating patterns, and the plurality of insulating patterns and the plurality of first contact holes may be alternately located along the first direction.

In an embodiment, the plurality of insulating layers may further include a second group of insulating layers between the second conductive pattern and the third conductive pattern, a second contact hole may penetrate the second group of insulating layers, and the second conductive pattern and the third conductive pattern may be connected to each other through the second contact hole.

In an embodiment, the first contact hole may be located inside the second contact hole in a plan view.

In an embodiment, the display device may further include: a thin film encapsulation layer on the pixel; and a sensing electrode on the thin film encapsulation layer. The sensing electrode may have a same stacked structure as that of the signal pad.

According to one or more embodiments of the present disclosure, a display device includes: a base layer; a pixel on the base layer; a signal line electrically connected to the pixel; a signal pad connected to the signal line; and a plurality of insulating layers on the base layer. The signal pad includes: a first conductive pattern connected to an end portion of the signal line; an insulating pattern on the first conductive pattern; a second conductive pattern contacting the first conductive pattern, and overlapping with a portion of an upper surface of the insulating pattern, the second conductive pattern having a first opening defined therein to expose a partial area of the upper surface of the insulating pattern and a part of side surfaces of the insulating pattern; and a third conductive pattern on the first conductive pattern, and overlapping with the portion of the upper surface of the insulating pattern, the third conductive pattern having a second opening defined therein to expose the partial area of the upper surface of the insulating pattern and a part of the side surfaces of the insulating pattern. The plurality of insulating layers includes a first group of insulating layers between the end portion of the signal line and the first conductive pattern, and the end portion of the signal line and the first conductive pattern are connected to each other through a first contact hole defined in the first group of insulating layers.

In an embodiment, the end portion of the signal line may extend in a first direction in a plan view, a first area may be an area of the upper surface of the insulating pattern where the second conductive pattern and the third conductive pattern overlap with each other, a second area may be an area of the upper surface of the insulating pattern where the second conductive pattern is located and the third conductive pattern is not located, a third area may be an area of the upper surface of the insulating pattern where the third conductive pattern is located and the second conductive pattern is not located, and the second area and the third area may face each other in a second direction crossing the first direction.

In an embodiment, a fourth area may be the partial area of the upper surface of the insulating pattern exposed from the second conductive pattern and the third conductive pattern, and the fourth area may include a fourth-first area and a fourth-second area spaced from each other in the first direction.

In an embodiment, the end portion of the signal line may extend in a first direction in a plan view, the first contact hole may include a plurality of first contact holes, the plurality of first contact holes may be located along the first direction, the insulating pattern may include a plurality of insulating patterns, and the plurality of insulating patterns and the plurality of first contact holes may be alternately located along the first direction.

According to one or more embodiments of the present disclosure, an electronic device includes: a display device; and a housing accommodating the display device. The display device includes: a base layer; a pixel on the base layer; a signal line electrically connected to the pixel; a signal pad connected to the signal line; and a plurality of insulating layers on the base layer. The signal pad includes: a first conductive pattern connected to an end portion of the signal line; an insulating pattern on the first conductive pattern; a second conductive pattern contacting the first conductive pattern, the second conductive pattern including a portion located on a part of an area of an upper surface of the insulating pattern; and a third conductive pattern on the first conductive pattern, the third conductive pattern including a portion overlapping with the portion of the second conductive pattern on the upper surface of the insulating pattern. A partial area of the upper surface of the insulating pattern is exposed from the second conductive pattern and the third conductive pattern. The plurality of insulating layers includes a first group of insulating layers between the end portion of the signal line and the first conductive pattern, and the end portion of the signal line and the first conductive pattern are connected to each other through a first contact hole defined in the first group of insulating layers.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1A is a perspective view of an electronic device according to an embodiment of the present disclosure.

FIG. 1B is an exploded perspective view of the electronic device according to an embodiment of the present disclosure.

FIG. 2 is a sectional view of a display device according to an embodiment of the present disclosure.

FIG. 3 is a plan view of a display panel according to an embodiment of the present disclosure.

FIG. 4 is a sectional view of the display panel according to an embodiment of the present disclosure.

FIG. 5A is a sectional view of an input sensor according to an embodiment of the present disclosure.

FIG. 5B is a plan view of the input sensor according to an embodiment of the present disclosure.

FIG. 5C is a sectional view corresponding to the line X-X′ of FIG. 5B.

FIG. 6 is an enlarged exploded perspective view of pad areas of the display device according to an embodiment of the present disclosure.

FIG. 7A is a plan view of the pad areas according to an embodiment of the present disclosure.

FIGS. 7B-7D are sectional views corresponding to the pad areas of FIG. 7A.

FIG. 8 is a sectional view illustrating a bonding structure of the electronic device according to an embodiment of the present disclosure.

FIGS. 9A-9D are plan views of the pad areas according to some embodiments of the present disclosure.

FIG. 10 is a plan view of the pad areas according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

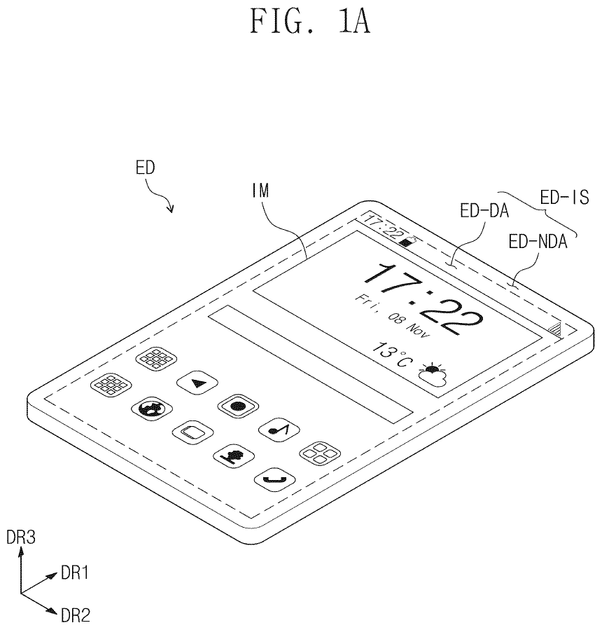

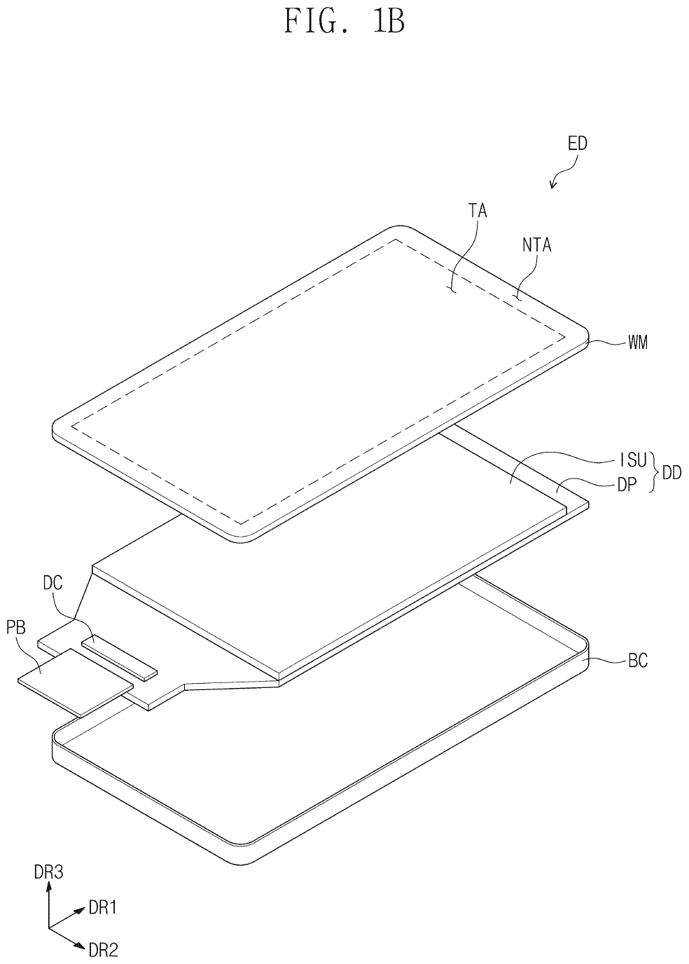

FIG. 1A is a perspective view of an electronic device ED according to an embodiment of the present disclosure. FIG. 1B is an exploded perspective view of the electronic device ED according to an embodiment of the present disclosure.

In FIGS. 1A and 1B, a mobile phone is illustrated as an example of the electronic device ED. However, the present disclosure is not limited thereto, and the electronic device ED may be implemented as or applied to various suitable small-sized and medium-sized electronic devices, such as a tablet computer, a car navigation unit (e.g., a car navigator), a game machine, and a smart watch, as well as various suitable large-sized electronic devices, such as a television and a monitor.

Referring to FIG. 1A, the electronic device ED may display an image IM through a display surface ED-IS. Icon images are illustrated as an example of the image IM. The display surface ED-IS may be parallel to or substantially parallel to a plane defined by a first direction DR1 and a second direction DR2. The normal direction of the display surface ED-IS, or in other words, the thickness direction of the electronic device ED, may be indicated by a third direction DR3. As used herein, the expressions “when viewed from above the plane or on the plane” and “in a plan view” may mean a view in/from the third direction DR3. Front surfaces (e.g., upper surfaces) and rear surfaces (e.g., lower surfaces) of the layers or units described in more detail below may be distinguished from each other based on the third direction DR3.

The display surface ED-IS includes a display area ED-DA on which the image IM is displayed, and a non-display area ED-NDA adjacent to the display area ED-DA. The non-display area ED-NDA is an area where an image is not displayed. However, the present disclosure is not limited thereto, and the non-display area ED-NDA may be adjacent to one side (e.g., to only one side) of the display area ED-DA, or may be omitted as needed or desired.

Referring to FIG. 1B, the electronic device ED may include a window WM, a display device DD, and a housing BC. The housing BC may accommodate the display device DD, and may be connected with (e.g., coupled with or attached to) the window WM. In some embodiments, the electronic device ED may further include other electronic modules accommodated in the housing BC, and electrically connected with the display device DD. For example, the electronic device ED may further include a main board, and a circuit module (e.g., a circuit or a circuit board), a camera module (e.g., a camera or a camera sensor), and a power module (e.g., a power supply or a power circuit) mounted on the main board.

The window WM may be disposed on the display device DD, and may transmit an image provided from the display device DD to the outside. The window WM includes a transmissive area TA and a non-transmissive area NTA. The transmissive area TA may overlap with the display area ED-DA, and may have a suitable shape corresponding to that of the display area ED-DA.

The non-transmissive area NTA may overlap with the non-display area ED-NDA, and may have a suitable shape corresponding to that of the non-display area ED-NDA. The non-transmissive area NTA may have a lower light transmittance than that of the transmissive area TA. A bezel pattern may be disposed on a partial area of a base layer. The area where the bezel pattern is disposed may be the non-transmissive area NTA, and the area where the bezel pattern is not disposed may be the transmissive area TA. The base layer of the window WM may be formed of glass, sapphire, or a plastic. However, the present disclosure is not limited thereto, and the non-transmissive area NTA may be omitted as needed or desired.

The display device DD may generate an image, and may sense an external input. The display device DD may include a display panel DP and an input sensor ISU. In some embodiments, the display device DD may further include an anti-reflective member disposed on the input sensor ISU. The anti-reflective member may include a polarizer and a retarder, or may include a color filter and a black matrix.

According to an embodiment of the present disclosure, the display panel DP may be an emissive display panel, but the kind thereof is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include a quantum dot, a quantum rod, or a nano LED. Hereinafter, the display panel DP will be described in more detail in the context of an organic light emitting display panel as a representative example.

The input sensor ISU may include one of a capacitive sensor, an optical sensor, an ultrasonic sensor, or an electromagnetic induction sensor. The input sensor ISU may be formed on the display panel DP through a continuous process, or may be manufactured separately from the display panel DP and then attached to the upper side of the display panel DP through an adhesive layer.

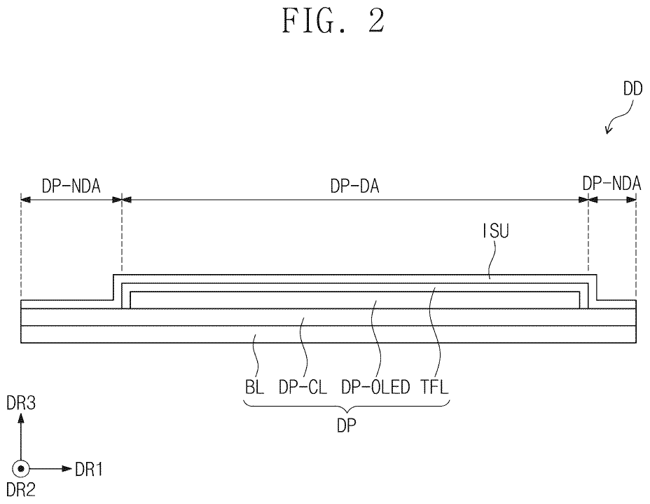

The display device DD may further include a driver chip DC and a circuit board PB. Although FIG. 1B illustrates an embodiment in which the driver chip DC is mounted on the display panel DP, the present disclosure is not limited thereto. The driver chip DC may generate a drive signal used for an operation of the display panel DP, based on a control signal transferred from the circuit board PB. The circuit board PB bonded to the display panel DP may be bent and disposed on the rear surface of the display panel DP. The circuit board PB may be disposed at one end of a base layer BL (e.g., see FIG. 2), and may be electrically connected to a circuit element layer DP-CL.

Although FIG. 1B illustrates an embodiment in which the circuit board PB is bent, the present disclosure is not limited thereto. A portion of the display panel DP may be bent, such that the driver chip DC faces downward. A non-display area of the display panel DP may be bent.

Although the mobile phone has been described as an example of the electronic device ED, in other embodiments, the electronic device ED may refer to any suitable device that includes two or more bonded electronic parts. The display panel DP and the driver chip DC mounted on the display panel DP may correspond to different electronic parts from each other, and the electronic device ED may be constituted by only the display panel DP and the driver chip DC. As another example, the electronic device ED may be constituted by only the display panel DP and the circuit board PB connected to the display panel DP. In another example, the electronic device ED may be constituted by only the main board and the electronic modules mounted on the main board. Hereinafter, for convenience of illustration, the electronic device ED will be described in more detail focusing on a bonding structure of the display panel DP and the driver chip DC mounted on the display panel DP.

FIG. 2 is a sectional view of the display device DD according to an embodiment of the present disclosure.

Referring to FIG. 2, the display panel DP includes the base layer BL, and the circuit element layer DP-CL, a display element layer DP-OLED, and an upper insulating layer TFL disposed on the base layer BL. The input sensor ISU may be disposed on the upper insulating layer TFL.

The display panel DP includes a display area DP-DA and a non-display area DP-NDA. The display area DP-DA of the display panel DP corresponds to the display area ED-DA described above with reference to FIG. 1A, or the transmissive area TA described above with reference to FIG. 1B. The non-display area DP-NDA corresponds to the non-display area ED-NDA described above with reference to FIG. 1A, or the non-transmissive area NTA described above with reference to FIG. 1B.

The base layer BL may include a synthetic resin film. The base layer BL may have a multi-layered structure. For example, the base layer BL may have a three-layered structure including a synthetic resin layer, an inorganic layer, and a synthetic resin layer. In more detail, the synthetic resin layers may be polyimide-based resin layers, but the material thereof is not particularly limited thereto. The synthetic resin layers may include at least one of an acrylic resin, a methacrylic resin, a polyisoprene resin, a vinyl resin, an epoxy resin, a urethane-based resin, a celluosic resin, a siloxane-based resin, a polyamide resin, or a perylene-based resin. In addition, the base layer BL may include a glass substrate, a metal substrate, or an organic/inorganic composite substrate.

The circuit element layer DP-CL may include at least one insulating layer and a circuit element. The insulating layer may include at least one inorganic layer and at least one organic layer. The circuit element may include signal lines and a pixel drive circuit. An insulating layer, a semiconductor layer, and a conductive layer may be formed through a suitable process, such as coating, deposition, or the like. Thereafter, the insulating layer, the semiconductor layer, and the conductive layer may be selectively subjected to patterning through a photolithography process and an etching process. A semiconductor pattern, a conductive pattern, and a signal line may be formed through these processes. Patterns disposed at (e.g., in or on) the same layer as each other may be formed through the same process as each other. Hereinafter, when patterns are described as being formed through the same process as each other, this means that the patterns include the same material as each other, and may have the same stacked structure as each other.

The display element layer DP-OLED may include an organic light emitting element. The display element layer DP-OLED may further include an organic layer, such as a pixel define layer.

The upper insulating layer TFL seals the display element layer DP-OLED.

For example, the upper insulating layer TFL may include a thin film encapsulation layer. The thin film encapsulation layer may include a stacked structure of an inorganic layer/an organic layer/an inorganic layer. The upper insulating layer TFL protects the display element layer DP-OLED from foreign matter, such as moisture, oxygen, and dust particles. However, the present disclosure is not limited thereto, and the upper insulating layer TFL may further include an additional insulating layer in addition to the thin film encapsulation layer. For example, the upper insulating layer TFL may further include an optical insulating layer for controlling a refractive index.

In an embodiment of the present disclosure, an encapsulation substrate may be provided, instead of the upper insulating layer TFL. In this case, the encapsulation substrate may be opposite to the base layer BL, and the circuit element layer DP-CL and the display element layer DP-OLED may be disposed between the encapsulation substrate and the base layer BL.

The input sensor ISU may be directly disposed on the display panel DP. As used herein, the expression “component A is directly disposed on component B” means that an adhesive layer is not disposed between component A and component B. In the present embodiment, the input sensor ISU may be manufactured together with the display panel DP through a continuous process. However, the present disclosure is not limited thereto, and the input sensor ISU may be provided as a separate panel and may be connected with (e.g., coupled with or attached to) the display panel DP through an adhesive layer. According to an embodiment, the input sensor ISU may be omitted as needed or desired.

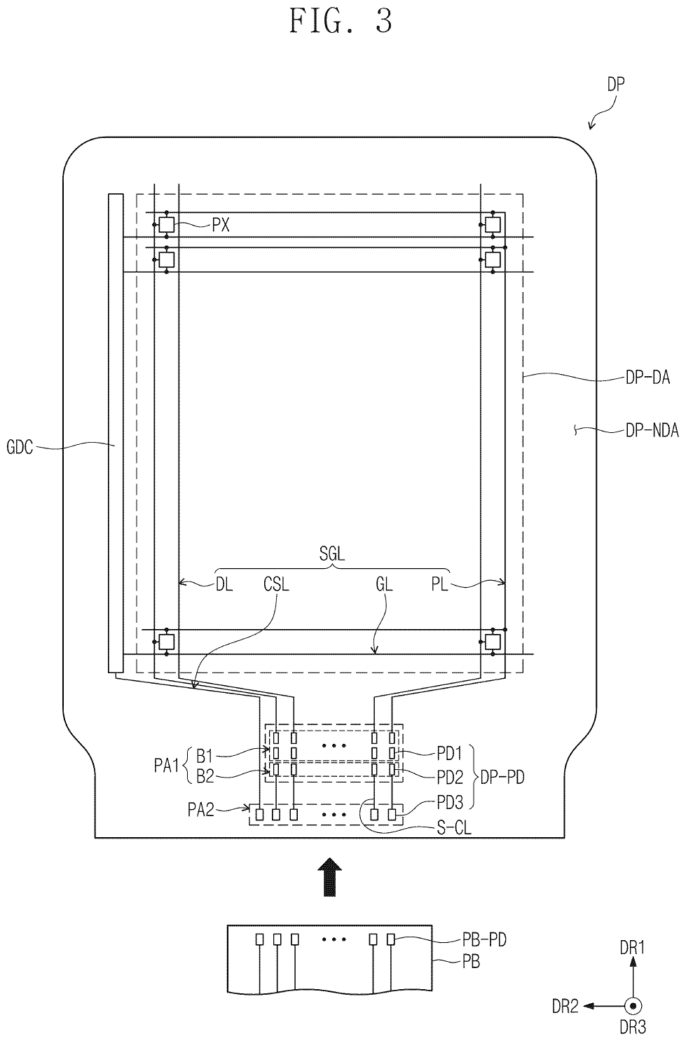

FIG. 3 is a plan view of the display panel DP according to an embodiment of the present disclosure.

Referring to FIG. 3, the display panel DP may include a plurality of pixels PX, a gate drive circuit GDC, a plurality of signal lines SGL, and a plurality of signal pads DP-PD.

The pixels PX are disposed in the display area DP-DA. Each of the pixels PX includes a light emitting element, and a pixel drive circuit connected to the light emitting element. The gate drive circuit GDC may sequentially output gate signals to a plurality of gate lines GL described in more detail below. A transistor of the gate drive circuit GDC and a transistor of the pixel PX may be formed through the same process as each other, for example, such as a low-temperature polycrystalline silicon (LTPS) process or a low-temperature polycrystalline oxide (LTPO) process. The display panel DP may further include another drive circuit that provides a light emission control signal to the pixels PX.

The signal lines SGL include the gate lines GL, data lines DL, a power line PL, and a control signal line CSL. Each of the gate lines GL is connected to a corresponding pixel or pixels PX, and each of the data lines DL is connected to a corresponding pixel or pixels PX. The power line PL is connected to the pixels PX. The control signal line CSL may be connected to the gate drive circuit GDC, and may provide control signals to the gate drive circuit GDC.

The signal lines SGL overlap with the display area DP-DA and the non-display area DP-NDA. Each of the signal lines SGL may include a pad and a line. The line overlaps with the display area DP-DA and the non-display area DP-NDA. The pad is connected to an end of the line. The pad may overlap with a pad area described in more detail below.

The signal lines SGL may be disposed at (e.g., in or on) one layer, and may have a one-body shape, but the present disclosure is not limited thereto. One signal line SGL may include a plurality of portions that are disposed at (e.g., in or on) different layers from each other. For example, the line may include two or more portions that are disposed at (e.g., in or on) different layers from each other in the non-display area DP-NDA.

The plurality of signal pads DP-PD may include first pads PD1, second pads PD2, and third pads PD3. The area where the first pads PD1 and the second pads PD2 are disposed may be defined as a first pad area PA1. The area where the third pads PD3 are disposed may be defined as a second pad area PA2.

The first pad area PA1 may be an area bonded with the driver chip DC (e.g., refer to FIG. 1B), and the second pad area PA2 may be an area bonded with the circuit board PB. The first pad area PA1 may include a first area B1 where the first pads PD1 are disposed, and a second area B2 where the second pads PD2 are disposed. The first pad area PA1 and the second pad area PA2 may be disposed in the non-display area DP-NDA. The first pad area PA1 and the second pad area PA2 may be spaced apart from each other in the first direction DR1.

Although two pad rows are illustrated in the first area B1, the present disclosure is not limited thereto, and more pad rows may be disposed in the first area B1. As another example, like the second area B2, the first area B1 may have one pad row disposed therein.

Each of the first pads PD1 may be connected to a corresponding data line DL. In some embodiments, the first pads PD1 and the second pads PD2 may be electrically connected with one another. The second pads PD2 may be connected with the third pads PD3 through connecting signal lines S-CL.

The circuit board PB may include a plurality of circuit pads PB-PD. The circuit pads PB-PD may be arranged along the second direction DR2. The circuit pads PB-PD of the circuit board PB may be bonded with the third pads PD3. A bonding structure of the circuit pads PB-PD of the circuit board PB and the third pads PD3 may be the same as, or different from, a bonding structure of a bump of the driver chip DC and the first pad PD1 or the second pad PD2 as described in more detail below.

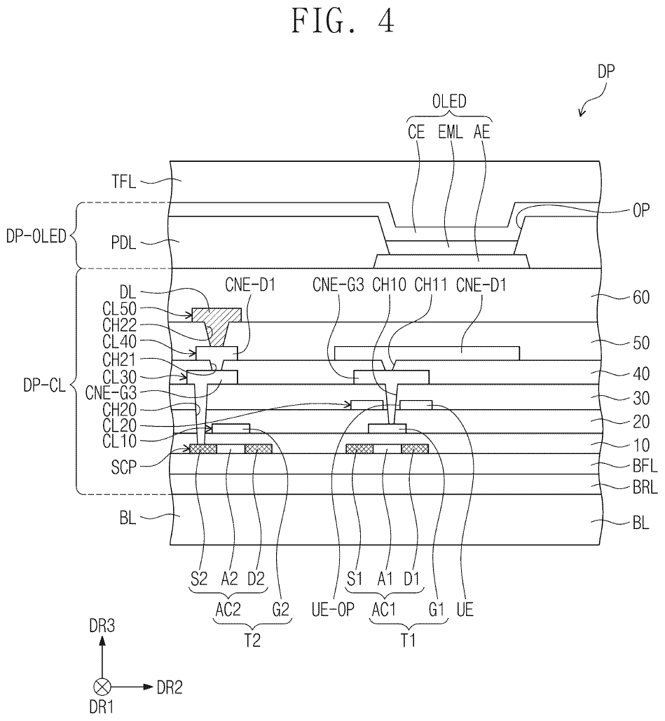

FIG. 4 is a sectional view of the display panel DP according to an embodiment of the present disclosure.

Referring to FIG. 4, the display panel DP may include the base layer BL, and the circuit element layer DP-CL, the display element layer DP-OLED, and the upper insulating layer TFL disposed on the base layer BL. A first transistor T1 and a second transistor T2 are illustrated as a drive circuit of a pixel.

A plurality of insulating layers are disposed on the upper surface of the base layer BL. The plurality of insulating layers may include a barrier layer BRL and a buffer layer BFL. The plurality of insulating layers may further include first to sixth insulating layers 10 to 60. The barrier layer BRL prevents or substantially prevents infiltration of foreign matter from the outside. The barrier layer BRL may include a silicon oxide layer and a silicon nitride layer. A plurality of silicon oxide layers and a plurality of silicon nitride layers may be provided. The silicon oxide layers and the silicon nitride layers may be alternately stacked one above another.

The buffer layer BFL improves a coupling force between the base layer BL and a semiconductor pattern and/or a conductive pattern. The buffer layer BFL may include silicon oxide layers and silicon nitride layers. The silicon oxide layers and the silicon nitride layers may be alternately stacked one above another.

A semiconductor pattern SCP may be disposed on the buffer layer BFL. The semiconductor pattern may include an amorphous silicon semiconductor, a polycrystalline silicon semiconductor, or a metal oxide semiconductor. As illustrated in FIG. 4, the semiconductor pattern SCP may include a first semiconductor area AC1 and a second semiconductor area AC2. The first semiconductor area AC1 may include a source area S1, a channel area A1, and a drain area D1 of the first transistor T1. The second semiconductor area AC2 may include a source area S2, a channel area A2, and a drain area D2 of the second transistor T2. In an embodiment of the present disclosure, the first transistor T1 and the second transistor T2 may include different semiconductors from each other. The second transistor T2 may include a material different from the material of the first semiconductor area AC1, and may be disposed at (e.g., in or on) a layer different from the layer at (e.g., in or on) which the first semiconductor area AC1 is disposed.

The first insulating layer 10 is disposed on the buffer layer BFL. The first insulating layer 10 may cover the semiconductor pattern SCP. The first insulating layer 10 may be an inorganic layer, but the present disclosure is not limited thereto. A first conductive layer CL10 is disposed on the first insulating layer 10. The first conductive layer CL10 may include a plurality of conductive patterns. The first conductive layer CL10 may include a gate G1 of the first transistor T1 and a gate G2 of the second transistor T2. The first conductive layer CL10 may include molybdenum (Mo), an alloy containing molybdenum, titanium (Ti), an alloy containing titanium, or the like having good heat resistance, but the present disclosure is not limited thereto. The first conductive layer CL10 may have a single-layer structure or a multi-layered structure.

The second insulating layer 20 that covers the first conductive layer CL10 is disposed on the first insulating layer 10. The second insulating layer 20 may be an inorganic layer, but the present disclosure is not limited thereto. A second conductive layer CL20 is disposed on the second insulating layer 20. The second conductive layer CL20 may include a plurality of conductive patterns. The second conductive layer CL20 may include an upper electrode UE. The upper electrode UE may overlap with the gate G1 of the first transistor T1, and may have an opening UE-OP formed therein. The gate G1 of the first transistor T1 and the upper electrode UE that overlap with each other may define a capacitor.

The third insulating layer 30 that covers the second conductive layer CL20 is disposed on the second insulating layer 20. The third insulating layer 30 may be an inorganic layer, but the present disclosure is not limited thereto. A third conductive layer CL30 is disposed on the third insulating layer 30. The third conductive layer CL30 may include a plurality of conductive patterns. The third conductive layer CL30 may include connecting electrodes CNE-G3. One connecting electrode CNE-G3 is connected to the gate G1 of the first transistor T1 through a contact hole CH10 that penetrates the second insulating layer 20 and the third insulating layer 30. The contact hole CH10 passes through the opening UE-OP. Another connecting electrode CNE-G3 may be connected to the source area S2 of the second transistor T2 through a contact hole CH20 that penetrates the first insulating layer 10, the second insulating layer 20, and the third insulating layer 30. The third conductive layer CL30 may further include a plurality of connecting electrodes.

The fourth insulating layer 40 that covers the third conductive layer CL30 is disposed on the third insulating layer 30. The fourth insulating layer 40 may be an inorganic layer, but the present disclosure is not limited thereto. A fourth conductive layer CL40 is disposed on the fourth insulating layer 40. The fourth conductive layer CL40 may include a plurality of conductive patterns. The fourth conductive layer CL40 may include connecting electrodes CNE-D1. The connecting electrodes CNE-D1 may be connected to the connecting electrodes CNE-G3, respectively, through contact holes CH11 and CH21 penetrating the fourth insulating layer 40.

The fifth insulating layer 50 that covers the fourth conductive layer CL40 is disposed on the fourth insulating layer 40. The fifth insulating layer 50 may be an organic layer, but the present disclosure is not limited thereto. A fifth conductive layer CL50 is disposed on the fifth insulating layer 50. The fifth conductive layer CL50 may include a plurality of conductive patterns. The fifth conductive layer CL50 may include a data line DL. The data line DL may be connected to a corresponding connecting electrode CNE-D1 through a contact hole CH22 penetrating the fifth insulating layer 50. The fifth conductive layer CL50 may further include a connecting electrode.

The sixth insulating layer 60 that covers the fifth conductive layer CL50 is disposed on the fifth insulating layer 50. The sixth insulating layer 60 may be an organic layer, but the present disclosure is not limited thereto. A light emitting element OLED is disposed on the sixth insulating layer 60. A first electrode AE of the light emitting element OLED is disposed on the sixth insulating layer 60. The first electrode AE may be an anode. A pixel define layer PDL is disposed on the sixth insulating layer 60.

An opening OP of the pixel define layer PDL exposes at least a portion of the first electrode AE. The opening OP of the pixel define layer PDL may define an emissive area. An emissive layer EML is disposed on the first electrode AE. Although a patterned emissive layer EML is illustrated in FIG. 4, the present disclosure is not limited thereto, and the emissive layer EML may be commonly disposed in the plurality of pixels PX (e.g., refer to FIG. 3). The commonly disposed emissive layer EML may generate white light or blue light. In addition, the emissive layer EML may have a multi-layered structure.

In some embodiments, a hole control layer may be additionally disposed between the first electrode AE and the emissive layer EML. The hole control layer may include a hole transport layer and/or a hole injection layer. The hole injection layer may be disposed between the hole transport layer and the first electrode AE. The hole transport layer or the hole injection layer may be commonly disposed in the plurality of pixels PX (e.g., refer to FIG. 3).

A second electrode CE is disposed on the emissive layer EML. In some embodiments, an electron control layer may be additionally disposed between the second electrode CE and the emissive layer EML. The electron control layer may include an electron transport layer and/or an electron injection layer. The electron injection layer may be disposed between the electron transport layer and the second electrode CE. The electron transport layer or the electron injection layer may be commonly disposed in the plurality of pixels PX (e.g., refer to FIG. 3).

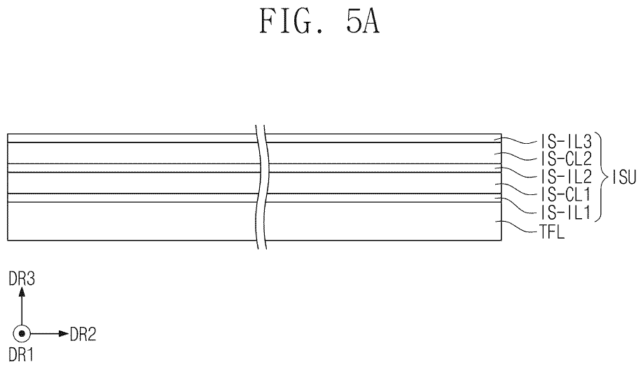

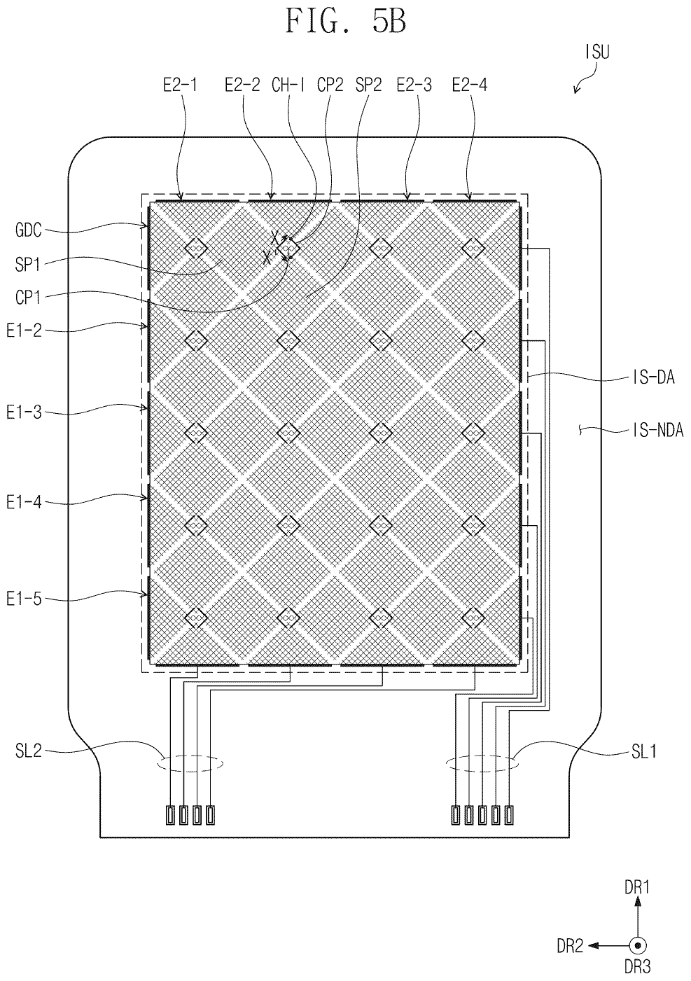

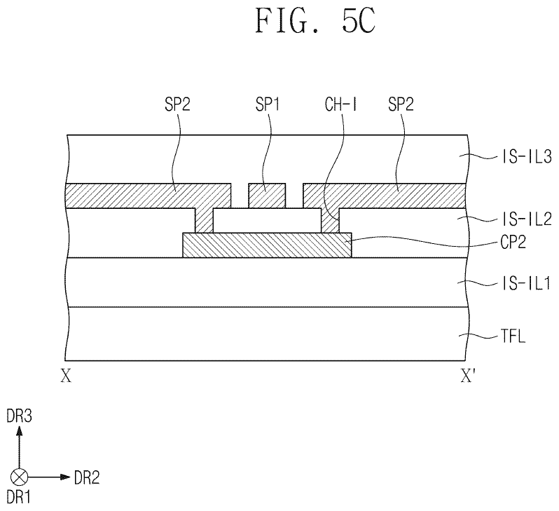

FIG. 5A is a sectional view of the input sensor ISU according to an embodiment of the present disclosure. FIG. 5B is a plan view of the input sensor ISU according to an embodiment of the present disclosure. FIG. 5C is a sectional view corresponding to the line X-X′ of FIG. 5B. For example, FIG. 5C may be a sectional view of a bridge pattern of the input sensor ISU according to an embodiment of the present disclosure.

The input sensor ISU may include a first insulating layer IS-IL1 (hereinafter, referred to as a first sensor insulating layer), a first conductive pattern layer IS-CL1, a second insulating layer IS-IL2 (hereinafter, referred to as a second sensor insulating layer), a second conductive pattern layer IS-CL2, and a third insulating layer IS-IL3 (hereinafter, referred to as a third sensor insulating layer). The first sensor insulating layer IS-IL1 may be directly disposed on the upper insulating layer TFL.

In an embodiment of the present disclosure, the first sensor insulating layer IS-IL1 and/or the third sensor insulating layer IS-IL3 may be omitted as needed or desired. When the first sensor insulating layer IS-IL1 is omitted, the first conductive pattern layer IS-CL1 may be disposed on the uppermost insulating layer of the upper insulating layer TFL. The third sensor insulating layer IS-IL3 may be replaced with an adhesive layer, or with an insulating layer of an anti-reflective member disposed on the input sensor ISU.

The first conductive pattern layer IS-CL1 may include first conductive patterns, and the second conductive pattern layer IS-CL2 may include second conductive patterns. Each of the first conductive pattern layer IS-CL1 and the second conductive pattern layer IS-CL2 may have a single-layer structure, or a multi-layered structure stacked in the third direction DR3. A conductive pattern having a multi-layered structure may include at least two of various suitable transparent conductive layers and/or metal layers. The multi-layered conductive pattern may include metal layers including different metals from each other. The transparent conductive layers may include indium tin oxide (ITO), indium zinc oxide (IZO), zinc oxide (ZnO), indium tin zinc oxide (ITZO), PEDOT, a metal nano-wire, or graphene. The metal layers may include molybdenum, silver, titanium, copper, aluminum, and/or an alloy thereof. A stacked structure of each of the first conductive pattern layer IS-CL1 and the second conductive pattern layer IS-CL2 will be described in more detail below.

In the present embodiment, each of the first to third sensor insulating layers IS-IL1, IS-IL2, and IS-IL3 may include an inorganic layer or an organic layer. The inorganic layer may include silicon oxide, silicon nitride, or silicon oxy nitride. In an embodiment of the present disclosure, at least one of the first to third sensor insulating layers IS-IL1, IS-IL2, and/or IS-IL3 may be an organic layer. For example, the third sensor insulating layer IS-IL3 may include an organic layer. The organic layer may include at least one of an acrylic resin, a methacrylic resin, a polyisoprene resin, a vinyl resin, an epoxy resin, a urethane-based resin, a celluosic resin, a siloxane-based resin, a polyimide resin, a polyamide resin, or a perylene-based resin.

Referring to FIG. 5B, the input sensor ISU includes a sensing area IS-DA, and a non-sensing area IS-NDA adjacent to the sensing area IS-DA. The sensing area IS-DA and the non-sensing area IS-NDA may correspond to the display area DP-DA and the non-display area DP-NDA, respectively, which are described above with reference to FIG. 2.

The input sensor ISU includes a plurality of sensing electrodes disposed in the sensing area IS-DA. The sensing electrodes may include first sensing electrodes E1-1 to E1-5 (hereinafter, referred to as first electrodes) and second sensing electrodes E2-1 to E2-4 (hereinafter, referred to as second electrodes) that cross each other while being insulated from each other. The sensing electrodes may have the same or substantially the same stacked structure as that of the signal pad DP-PD described in more detail below.

The input sensor ISU includes first signal lines SL1 disposed in the non-sensing area IS-NDA and electrically connected to the first electrodes E1-1 to E1-5, and second signal lines SL2 disposed in the non-sensing area IS-NDA and electrically connected to the second electrodes E2-1 to E2-4. The first electrodes E1-1 to E1-5, the second electrodes E2-1 to E2-4, the first signal lines SL1, and the second signal lines SL2 may be defined by a suitable combination of the conductive patterns of the first conductive pattern layer IS-CL1 and the second conductive pattern layer IS-CL2 described above with reference to FIG. 5A. In FIG. 5B, each of the first signal lines SL1 and the second signal lines SL2 is illustrated as having a one-body shape, but the present disclosure is not limited thereto. Each of the first signal lines SL1 and the second signal lines SL2 may include a plurality of portions disposed at (e.g., in or on) different layers from each other.

Each of the first electrodes E1-1 to E1-5 and the second electrodes E2-1 to E2-4 may include a plurality of conductive lines crossing one another. The plurality of conductive lines may define a plurality of openings, and each of the first electrodes E1-1 to E1-5 and the second electrodes E2-1 to E2-4 may have a mesh shape. Each of the plurality of openings may be defined to correspond to a corresponding opening OP of the pixel define layer PDL described above with reference to FIG. 4.

Each of the first electrodes E1-1 to E1-5 and the second electrodes E2-1 to E2-4 may have a one-body shape. In the present embodiment, the first electrodes E1-1 to E1-5, each of which has a one-body shape, are illustrated as an example. The first electrodes E1-1 to E1-5 may include sensing parts SP1 and intermediate parts CP1. A portion of the conductive pattern of the second conductive pattern layer IS-CL2 described above may correspond to the first electrodes E1-1 to E1-5.

Each of the second electrodes E2-1 to E2-4 may include sensing patterns SP2 and bridge patterns CP2 (e.g., connecting patterns). As illustrated in FIGS. 5B and 5C, two adjacent sensing patterns SP2 may be connected to two bridge patterns CP2 through contact holes CH-I penetrating the second sensor insulating layer IS-IL2, but the number of bridge patterns CP2 is not limited thereto. A portion of the conductive pattern of the second conductive pattern layer IS-CL2 described above may correspond to the sensing patterns SP2. A portion of the conductive pattern of the first conductive pattern layer IS-CL1 described above may correspond to the bridge patterns CP2.

In the present embodiment, the bridge patterns CP2 may be formed from the first conductive pattern layer IS-CL1 described above with reference to FIG. 5A, and the first electrodes E1-1 to E1-5 and the sensing patterns SP2 may be formed from the second conductive pattern layer IS-CL2. However, the present disclosure is not limited thereto. The first electrodes E1-1 to E1-5 and the sensing patterns SP2 may be formed from the first conductive pattern layer IS-CL1 described above with reference to FIG. 5A, and the bridge patterns CP2 may be formed from the second conductive pattern layer IS-CL2.

One of the first signal lines SL1 or the second signal lines SL2 may transfer a transmission signal for sensing an external input from an external circuit to corresponding electrodes among the first electrodes E1-1 to E1-5 and the second electrodes E2-1 to E2-4, and the other of the first signal lines SL1 or the second signal lines SL2 may transfer a change in capacitance between the first electrodes E1-1 to E1-5 and the second electrodes E2-1 to E2-4 to the external circuit as a reception signal.

A portion of the conductive pattern of the second conductive pattern layer IS-CL2 described above may correspond to the first signal lines SL1 and the second signal lines SL2. The first signal lines SL1 and the second signal lines SL2 may have a multi-layered structure, and may include a first layer line formed from the above-described first conductive pattern layer IS-CL1 and a second layer line formed from the above-described second conductive pattern layer IS-CL2. The first layer line and the second layer line may be connected to each other through a contact hole penetrating the second sensor insulating layer IS-IL2 (e.g., refer to FIG. 5A).

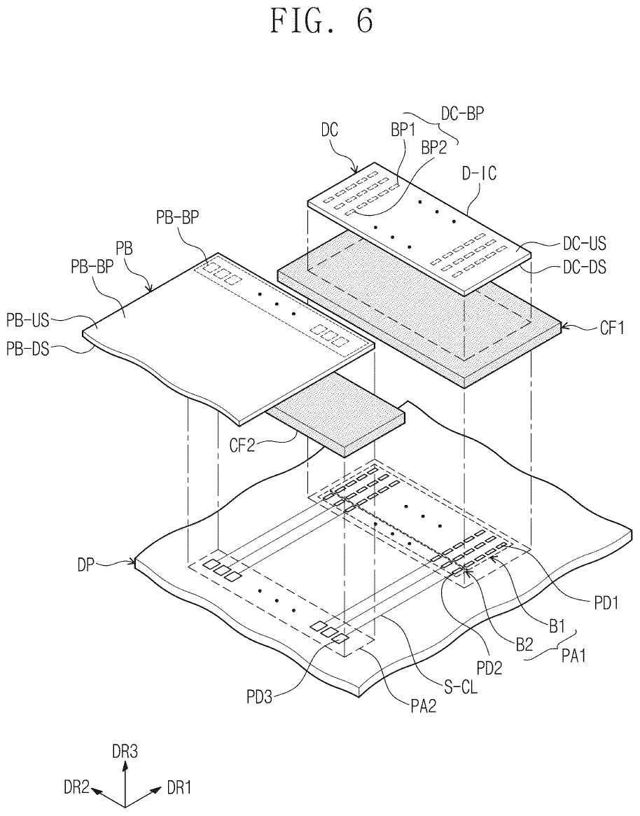

FIG. 6 is an enlarged exploded perspective view of the pad areas PA1 and PA2 of the display device DD according to an embodiment of the present disclosure. In FIG. 6, the driver chip DC and the circuit board PB are illustrated as being disassembled from the display panel DP. The first pads PD1, the second pads PD2, the connecting signal lines S-CL, and the third pads PD3 illustrated in FIG. 6 may be the same or substantially the same as those described above with reference to FIG. 3, and thus, redundant description thereabout may not be repeated.

The driver chip DC may be bonded to the first pad area PA1 through a first adhesive layer CF1. The circuit board PB may be bonded to the second pad area PA2 through a second adhesive layer CF2.

According to an embodiment of the present disclosure, the first adhesive layer CF1 and the second adhesive layer CF2 may be non-conductive films. In other words, the first adhesive layer CF1 and the second adhesive layer CF2 may not include conductive balls, and may include an adhesive synthetic resin. Because the synthetic resin does not have to maintain an arrangement of the conductive balls, it may have a relatively low viscosity.

The driver chip DC may include a driver integrated circuit D-IC, and chip bump electrodes DC-BP mounted in the driver chip DC. The driver integrated circuit D-IC may include an upper surface DC-US and a lower surface DC-DS. The lower surface DC-DS may be a surface that faces the first pads PD1 and the second pads PD2. The chip bump electrodes DC-BP may be disposed on the lower surface DC-DS of the driver integrated circuit D-IC.

The chip bump electrodes DC-BP may include first bumps BP1 electrically connected to the first pads PD1, and second bumps BP2 electrically connected to the second pads PD2, respectively. The first bumps BP1 may be arranged along the second direction DR2, and the second bumps BP2 may be spaced apart from the first bumps BP1 in the first direction DR1 and may be arranged along the second direction DR2.

The driver chip DC may receive first signals from the outside through the second pads PD2 and the second bumps BP2. The driver chip DC may provide second signals generated based on the first signals to the first pads PD1 through the first bumps BP1. For example, the driver chip DC may include a data drive circuit. The first signal may be an image signal that is a digital signal applied from the outside, and the second signal may be a data signal that is an analog signal. The driver chip DC may generate an analog voltage corresponding to a gray level value of the image signal. The data signal may be provided to the pixel PX through the data line DL described above with reference to FIG. 4.

In some embodiments, the first bumps BP1 and the second bumps BP2 may have a shape that protrudes from the lower surface DC-DS of the driver integrated circuit D-IC, and may be exposed to the outside. When the first adhesive layer CF1 is cured, the first pads PD1 and the first bumps BP1 may be fixed to be in contact with each other, and the second pads PD2 and the second bumps BP2 may be fixed to be in contact with each other.

The circuit board PB may include substrate bumps PB-BP mounted in the circuit board PB. The circuit board PB may include an upper surface PB-US and a lower surface PB-DS. The lower surface PB-DS may be a surface facing the third pads PD3. The substrate bumps PB-BP may be disposed on the lower surface PB-DS of the circuit board PB. The substrate bumps PB-BP may be electrically connected to the third pads PD3, respectively. The substrate bumps PB-BP may be arranged along the second direction DR2. The circuit board PB may provide an image signal, a drive voltage, and other suitable control signals to the driver chip DC.

In some embodiments, the substrate bumps PB-BP may have a shape that protrudes from the lower surface PB-DS of the circuit board PB, and may be exposed to the outside. When the second adhesive layer CF2 is cured, the third pads PD3 and the substrate bumps PB-BP may be fixed to be in contact with each other.

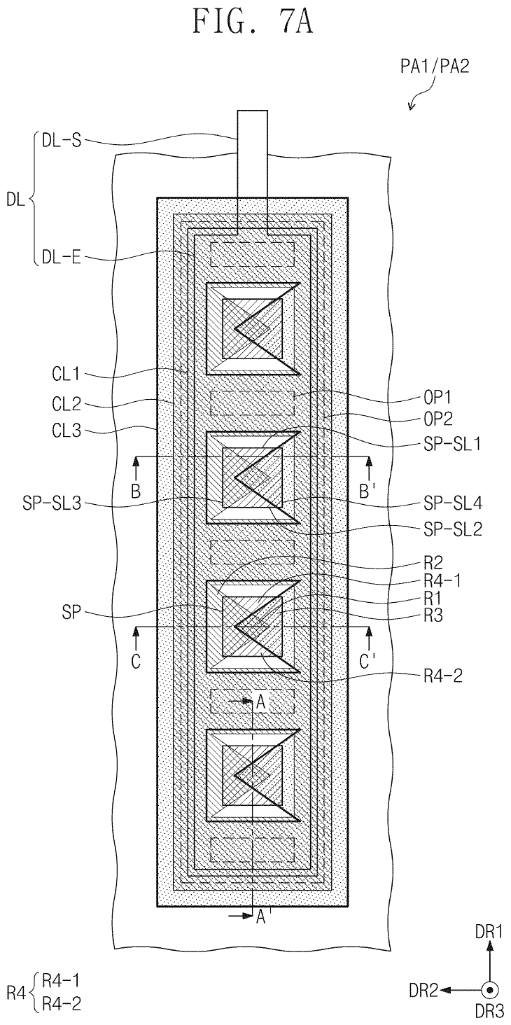

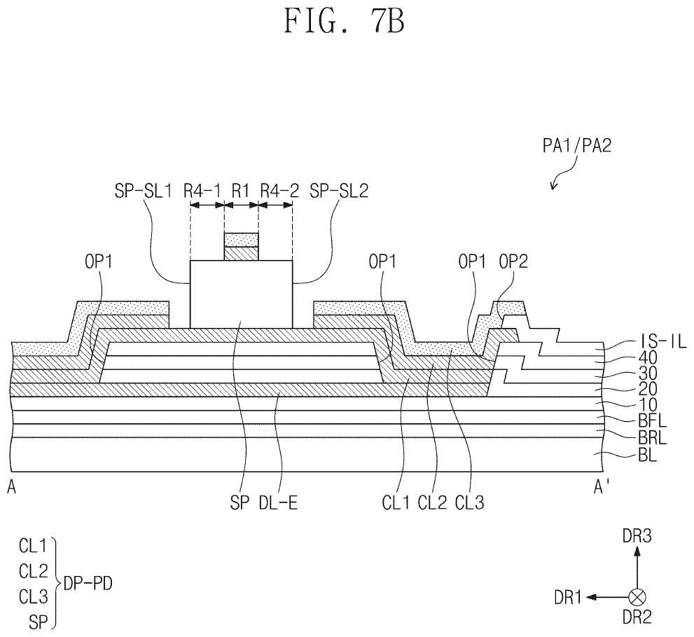

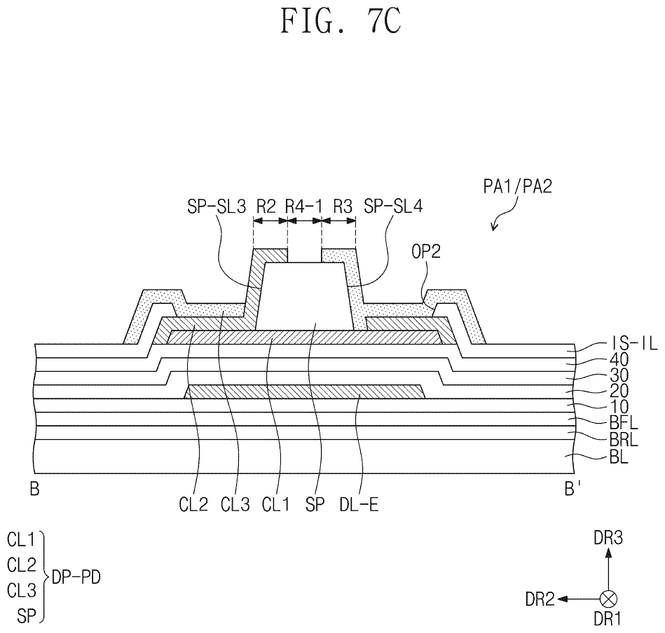

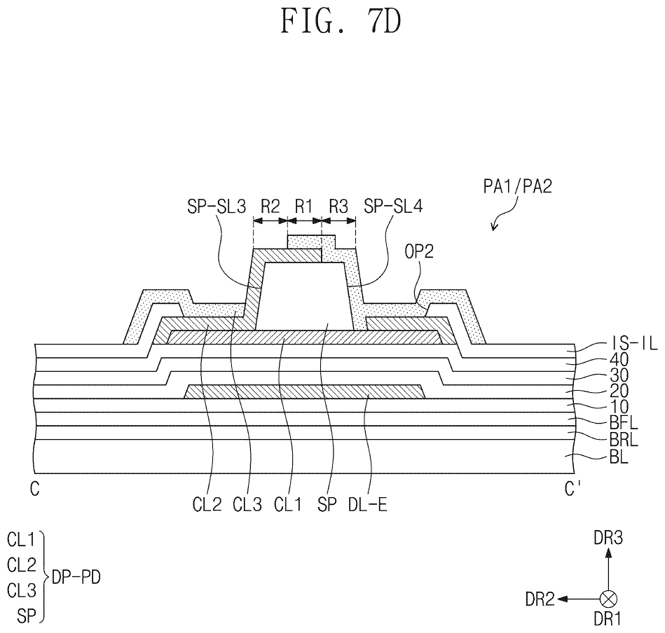

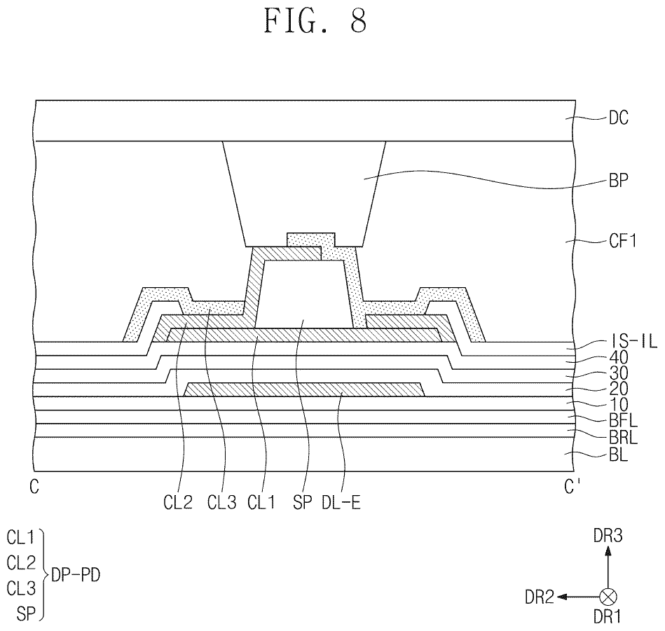

FIG. 7A is a plan view of the pad areas PA1 and PA2 according to an embodiment of the present disclosure. FIGS. 7B through 7D are sectional views corresponding to the pad areas PA1 and PA2 of FIG. 7A. For example, FIGS. 7B through 7D may be sectional views corresponding to the lines A-A′, B-B′, and C-C′ of FIG. 7A, respectively. FIG. 8 is a sectional view illustrating a bonding structure of the electronic device according to an embodiment of the present disclosure.

The signal pad DP-PD illustrated in FIG. 7A may be one of the first pads PD1, the second pads PD2, or the third pads PD3 described above with reference to FIGS. 3 and 6. In FIG. 7A, a data line DL including an end portion DL-E and a line portion DL-S having different widths from each other is illustrated as an example of a signal line. However, the present disclosure is not limited thereto. Here, the widths may refer to the lengths or the widths of the end portion DL-E and the line portion DL-S in the second direction DR2. The signal line may be another signal line other than the data line DL, and may have a uniform or substantially uniform width without distinction of the end portion DL-E and the line portion DL-S from each other.

Hereinafter, for convenience of illustration, the pad areas PA1 and PA2 will be described in more detail based on the first pad area PA1 where the data line DL is disposed. However, the second pad area PA2 may be the same or substantially the same as the first pad area PA1, except that the connecting signal line S-CL (e.g., refer to FIG. 3) is disposed instead of the data line DL, and thus, redundant description thereabout may not be repeated.

Referring to FIG. 7A, the signal pad DP-PD includes a first conductive pattern CL1 connected to the end portion DL-E of the signal line, an insulating pattern SP disposed on the first conductive pattern CL1, a second conductive pattern CL2 that contacts (e.g., that makes contact with) the first conductive pattern CL1 and has a portion disposed on a partial area of the upper surface of the insulating pattern SP, and a third conductive pattern CL3 that is disposed on the first conductive pattern CL1 and that overlaps with the portion of the second conductive pattern CL2 on the upper surface of the insulating pattern SP.

In FIG. 7A, five first contact holes OP1 and four insulating patterns SP are illustrated as an example. The four insulating patterns SP and the five first contact holes OP1 alternate with one another. The insulating patterns SP may be aligned with the first contact holes OP1 in the first direction DR1. Each of the insulating patterns SP may be disposed between two first contact holes OP1 closest to (e.g., adjacent to) each other among the first contact holes OP1.

The insulating pattern SP may include a polymer. The insulating pattern SP may include a thermosetting polymer. However, the present disclosure is not limited thereto, and the insulating pattern SP may include a thermoplastic polymer.

The first contact holes OP1 may overlap with the end portion DL-E when viewed from above the plane (e.g., in a plan view). The insulating patterns SP, when viewed from above the plane (e.g., in a plan view), may be disposed outside the first contact holes OP1, and may be disposed inside second contact holes OP2. In other words, the first contact holes OP1 may be disposed inside the second contact holes OP2.

The end portion DL-E may have a suitable shape extending in the first direction DR1. In other words, the length or the width of the end portion DL-E in the first direction DR1 may be greater than the length or the width of the end portion DL-E in the second direction DR2. The insulating patterns SP may be arranged along the first direction DR1. The insulating patterns SP may be spaced apart from one another in the first direction DR1.

The insulating patterns SP having a square shape when viewed from above the plane (e.g., in a plan view) are illustrated in FIGS. 7A to 7D. However, the present disclosure is not limited thereto. Each of the insulating patterns SP may have a suitable shape extending in the second direction DR2 crossing the first direction DR1 along which the insulating patterns SP are arranged. Each of the insulating patterns SP may have a quadrangular shape extending in the second direction DR2 when viewed from above the plane (e.g., in a plan view). However, the present disclosure is not limited thereto, and the shape of the insulating patterns SP may be variously modified as needed or desired, for example, such as to an oval shape extending in the second direction DR2 or a polygonal shape different from the quadrangular shape. The insulating patterns SP may have the same or substantially the same shape as each other, but the present disclosure is not limited thereto.

Referring to FIGS. 7A to 7D, the end portion DL-E is disposed on the first insulating layer 10. The end portion DL-E is disposed at (e.g., in or on) the same layer as that of the gates G1 and G2 described above with reference to FIG. 4. The end portion DL-E may be formed through the same process as that of the gates G1 and G2.

However, the position of the end portion DL-E on the cross-section is not limited thereto. The end portion DL-E may be disposed at (e.g., in or on) the same layer as that of the upper electrode UE or as that of the connecting electrodes CNE-G3 of the third conductive layer CL30 described above with reference to FIG. 4, and may include the same material and stacked structure as that of the upper electrode UE or as that of the connecting electrodes CNE-G3 of the third conductive layer CL30. The end portions DL-E of the plurality of data lines DL are not all limited to being disposed at (e.g., in or on) the same layer as each other.

The data line DL may be disposed at (e.g., in or on) one layer, and may have a one-body shape, but the present disclosure is not limited thereto. One data line DL may include a plurality of portions disposed at (e.g., in or on) different layers from each other. For example, the line portion DL-S may include two or more portions.

The signal pad DP-PD illustrated in FIG. 7B may include the first conductive pattern CL1 connected to the end portion DL-E and the insulating pattern SP, and the second conductive pattern CL2 and the third conductive pattern CL3 that are disposed on the first conductive pattern CL1. The end portion DL-E, the first conductive pattern CL1, the second conductive pattern CL2, and the third conductive pattern CL3 may be distinguished from one another depending on whether or not the insulating layers 20 to IS-IL are disposed therebetween, or whether or not a connection therebetween is formed through the contact holes OP1 and OP2. More detailed description thereof will be given below.

The first conductive pattern CL1 is disposed on the end portion DL-E and the fourth insulating layer 40. The first conductive pattern CL1 may be connected to the end portion DL-E through the first contact hole OP1 that penetrates the second insulating layer 20, the third insulating layer 30, and the fourth insulating layer 40. The second insulating layer 20, the third insulating layer 30, and the fourth insulating layer 40 may be formed through the same process as those of the second insulating layer 20, the third insulating layer 30, and the fourth insulating layer 40 of the display area DP-DA described above with reference to FIG. 4. A stacked structure of the insulating layers through which the first contact hole OP1 passes may be variously modified depending on the stacked structure of the circuit element layer DP-CL. In an embodiment, the first contact hole OP1 may penetrate insulating layers that are greater in number than the number of the second to fourth insulating layers 20, 30, and 40, or may penetrate insulating layers that are fewer in number than the number of the second to fourth insulating layers 20, 30, and 40.

The first conductive pattern CL1 and the end portion DL-E may be distinguished from each other by the second to fourth insulating layers 20, 30, and 40 disposed therebetween. In the present embodiment, the second to fourth insulating layers 20, 30, and 40 may be defined as a first group of insulating layers. The stacked structure of the first group of insulating layers may be variously modified as needed or desired. In an embodiment of the present disclosure, the first contact hole OP1 may penetrate insulating layers that are greater in number than the number of the second to fourth insulating layers 20, 30, and 40.

The second conductive pattern CL2 may contact (e.g., may make contact with) the first conductive pattern CL1, and a portion of the second conductive pattern CL2 may be disposed on a partial area of the upper surface of the insulating pattern SP. The area of the second conductive pattern CL2 that does not overlap with the insulating pattern SP may contact (e.g., may be brought into contact with) the first conductive pattern CL1. An insulating layer may not be disposed between the first conductive pattern CL1 and the second conductive pattern CL2, and the first conductive pattern CL1 and the second conductive pattern CL2 may be connected to each other, but not through a contact hole. The first conductive pattern CL1 may be formed through the same process as that of the fourth conductive layer CL40 described above with reference to FIG. 4, and the second conductive pattern CL2 may be formed through the same process as that of the fifth conductive layer CL50. The fifth insulating layer 50 and the sixth insulating layer 60 described above with reference to FIG. 4 may not be disposed in the pad areas PA1 and PA2.

The third conductive pattern CL3 may be disposed on the first conductive pattern CL1, and a portion of the third conductive pattern CL3 may overlap with a portion of the second conductive pattern CL2 on the upper surface of the insulating pattern SP. The third conductive pattern CL3 is disposed on the sensor insulating layer IS-IL of the input sensor ISU. The sensor insulating layer IS-IL may include at least one of the first sensor insulating layer IS-IL1 or the second sensor insulating layer IS-IL2 described above with reference to FIGS. 5A to 5C. The third conductive pattern CL3 may include at least one of the first conductive pattern layer IS-CL1 or the second conductive pattern layer IS-CL2 described above with reference to FIGS. 5A to 5C.

In an embodiment of the present disclosure, the third conductive pattern CL3 may be formed through the same process as that of the second conductive pattern layer IS-CL2 described above with reference to FIG. 5A and the sensing patterns SP2 described above with reference FIG. 5C. Although the third conductive pattern CL3 having a greater width or length in the second direction DR2 than those of the first conductive pattern CL1 and the second conductive pattern CL2 is illustrated, the present disclosure is not limited thereto.

The third conductive pattern CL3 may be connected to the second conductive pattern CL2 through the second contact hole OP2 that penetrates the first sensor insulating layer IS-IL1 and the second sensor insulating layer IS-IL2 of the input sensor ISU. The first sensor insulating layer IS-IL1 and the second sensor insulating layer IS-IL2 may overlap with the sensing area IS-DA and the non-sensing area IS-NDA described above with reference to FIG. 5. Accordingly, the first sensor insulating layer IS-IL1 and the second sensor insulating layer IS-IL2 may overlap with the pad areas PA1 and PA2.

The second conductive pattern CL2 and the third conductive pattern CL3 may be distinguished from each other by the sensor insulating layer IS-IL located outside the second contact hole OP2 and disposed between the second conductive pattern CL2 and the third conductive pattern CL3. In the present embodiment, the sensor insulating layer IS-IL may be defined as a second group of insulating layers IS-IL.

As described above with reference to FIGS. 7A and 7B, a portion of the first conductive pattern CL1 that does not overlap with the first contact hole OP1 may be disposed on the fourth insulating layer 40. The insulating pattern SP may be disposed on the first conductive pattern CL1 inside the second contact hole OP2. A portion of the second conductive pattern CL2 that does not overlap with the first contact hole OP1 may be disposed on a partial area of the upper surface of the insulating pattern SP.

The third conductive pattern CL3 may contact (e.g., may make contact with) the second conductive pattern CL2 inside the second contact hole OP2. A portion of the third conductive pattern CL3 that does not overlap with the first contact hole OP1 may be disposed on the partial area of the upper surface of the insulating pattern SP. The portion of the third conductive pattern CL3 may overlap with the portion of the second conductive pattern CL2. In other words, the area of the upper surface of the insulating pattern SP that overlaps with the second conductive pattern CL2 and the third conductive pattern CL3 may be defined as a first area R1.

Both the second conductive pattern CL2 and the third conductive pattern CL3 may not be disposed on another partial area of the upper surface of the insulating pattern SP. In other words, a partial area of the upper surface of the insulating pattern SP that is exposed from the second conductive pattern CL2 and the third conductive pattern CL3 may be defined as a fourth area R4. The fourth area R4 may include a fourth-first area R4-1 and a fourth-second area R4-2 that are opposite to each other from the first area R1 in the first direction DR1. The fourth-first area R4-1 and the fourth-second area R4-2 may be opposite to each other with the first area R1 therebetween.

In the bonding process described above with reference to FIG. 6, the insulating pattern SP may be deformed by a bonding pressure and heat, and may absorb a portion of the bonding pressure. Because the second conductive pattern CL2 and the third conductive pattern CL3 overlap with each other on the upper surface of the insulating pattern SP, a capacity to absorb the bonding pressure and a recovery rate, which are unique characteristics of the insulating pattern SP, may be reduced. As a portion of the upper surface of the insulating pattern SP is exposed from the second conductive pattern CL2 and the third conductive pattern CL3, the insulating pattern SP may absorb a portion of the bonding pressure. Accordingly, after the bonding process, the insulating pattern SP may be more easily restored to a shape (e.g., an initial shape) before the bonding process. In addition, as the recovery rate of the insulating pattern SP is increased, a bonding reliability and a bonding strength may be increased, and thus, a durability of the display device may be improved.

A first side surface SP-SL1 and a second side surface SP-SL2 of the insulating pattern SP may be exposed by the second conductive pattern CL2 and the third conductive pattern CL3. A portion of the first conductive pattern CL1 may also be further exposed from the second conductive pattern CL2 and the third conductive pattern CL3. As the side surfaces of the insulating pattern SP are exposed, the insulating pattern SP may absorb a portion of the bonding pressure applied from the second conductive pattern CL2 and the third conductive pattern CL3. Accordingly, the recovery rate may be improved after the bonding process of the insulating pattern SP.

In addition, a first opening may be defined in the second conductive pattern CL2 to expose a partial area of the upper surface of the insulating pattern SP and a part of the side surfaces of the insulating pattern SP, and a second opening may be defined in the third conductive pattern CL3 to expose a partial area of the upper surface of the insulating pattern SP and a part of the side surfaces of the insulating pattern SP.

Referring to FIGS. 7A and 7C, the second conductive pattern CL2 may contact (e.g., may make contact with) a third side surface SP-SL3 of the insulating pattern SP. The second conductive pattern CL2 may be disposed on an area of the upper surface of the insulating pattern SP that is adjacent to the third side surface SP-SL3. In addition, the second conductive pattern CL2 may not contact (e.g., may not make contact with) a fourth side surface SP-SL4 of the insulating pattern SP, and may not be disposed on a partial area of the upper surface of the insulating pattern SP.

The third conductive pattern CL3 may contact (e.g., may make contact with) the fourth side surface SP-SL4 of the insulating pattern SP. The third conductive pattern CL3 may be disposed on an area of the upper surface of the insulating pattern SP that is adjacent to the fourth side surface SP-SL4. In addition, the third conductive pattern CL3 may not contact (e.g., may not make contact with) the third side surface SP-SL3 of the insulating pattern. The third conductive pattern CL3 may not be disposed on another partial area of the upper surface of the insulating pattern SP.

The second conductive pattern CL2 may be disposed on the area of the upper surface of the insulating pattern SP that is adjacent to the third side surface SP-SL3, and the third conductive pattern CL3 may not be disposed on the area of the upper surface of the insulating pattern SP that is adjacent to the third side surface SP-SL3. The area may be defined as a second area R2. The third conductive pattern CL3 may be disposed on the area of the upper surface of the insulating pattern SP that is adjacent to the fourth side surface SP-SL4, and the second conductive pattern CL2 may not be disposed on the area of the upper surface of the insulating pattern SP that is adjacent to the fourth side surface SP-SL4. The area may be defined as a third area R3. The second area R2 and the third area R3 may face or be opposite to each other in the second direction DR2. In addition, the upper surface of the insulating pattern SP may include the fourth-first area R4-1 on which both the second conductive pattern CL2 and the third conductive pattern CL3 are not disposed, and therefore, a step may be formed in the third direction DR3.

Referring to FIGS. 7A and 7D, the portion of the second conductive pattern CL2 disposed on the upper surface of the insulating pattern SP may include a first edge or end. The first edge or end may protrude in the second direction DR2 when viewed from above the plane (e.g., in a plan view). The portion of the third conductive pattern CL3 disposed on the upper surface of the insulating pattern SP may include a second edge or end facing an opposite direction of that of the first edge or end in the second direction DR2 when viewed from above the plane (e.g., in a plan view). The first edge or end and the second edge or end may overlap with each other on the upper surface of the insulating pattern SP.

The upper surface of the insulating pattern SP may include the first area R1 where the first edge or end and the second edge or end overlap with each other, the second area R2 where the second conductive pattern CL2 adjacent to the first edge or end is disposed, and the third area R3 where the third conductive pattern CL3 adjacent to the second edge or end is disposed. The first area R1 may be disposed between the second area R2 and the third area R3. The first area R1 may be stacked higher in the third direction DR3 than the second area R2 and the third area R3, and therefore, a step may be formed.

As the step is formed, a contact area between the pad PD1 or PD2 and the substrate bump PB-BP (e.g., refer to FIG. 6) or the bump DC-BP of the driver chip may be increased on the upper surface of the insulating pattern SP, and the pad PD1 or PD2 and the substrate bump PB-BP or the bump DC-BP of the driver chip may closely contact (e.g., may make close contact with) each other. Accordingly, during the bonding, a contact resistance may be reduced, and a mechanical coupling strength may be increased. Thus, a bonding reliability may be improved.

In FIG. 8, the driver chip DC is further illustrated as an electronic part. FIG. 8 illustrates a state in which the bump BP of the driver chip is brought into contact with the second conductive pattern CL2 and the third conductive pattern CL3.

The bump BP of the driver chip DC penetrates the first adhesive layer CF1 by the bonding pressure to contact (e.g., to make contact with) the second conductive pattern CL2 and the third conductive pattern CL3. Because the second conductive pattern CL2 and the third conductive pattern CL3 may protrude toward the bump BP from the upper surface of the insulating pattern SP, the second conductive pattern CL2 and the third conductive pattern CL3 may closely contact (e.g., may make close contact with) the bump BP, and the contact resistance therebetween may be reduced. Furthermore, the step between the second conductive pattern CL2 and the third conductive pattern CL3, which is formed on the upper surface of the insulating pattern SP, may replace a protrusion that may be formed on a surface of the bump BP. In other words, even when the surface of the bump BP is relatively smooth, the step may be formed, and thus, an accessibility between the bump BP and the signal pad DP-PD may be improved. Accordingly, a decrease in a bonding pressure and an increase in a bonding adhesion may be achieved. In addition, after the bonding process is completed, the insulating pattern SP, the side surfaces of which are exposed from the second conductive pattern CL2 and the third conductive pattern CL3, may be more easily restored to the shape (e.g., the initial shape) before the bonding process.

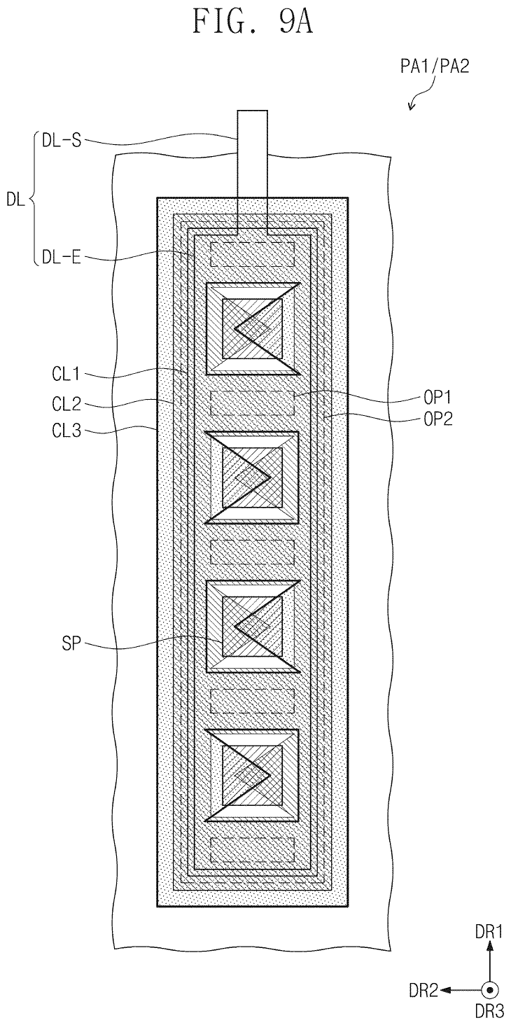

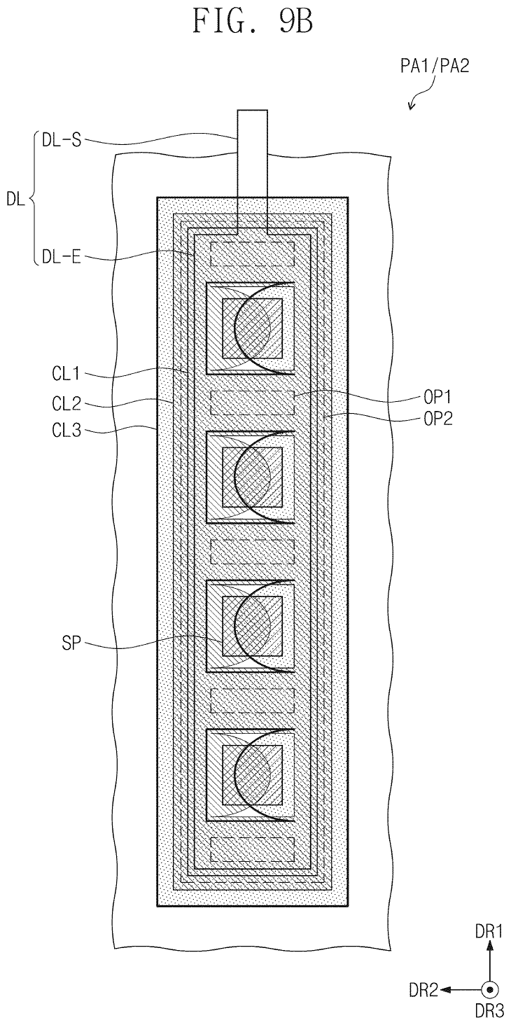

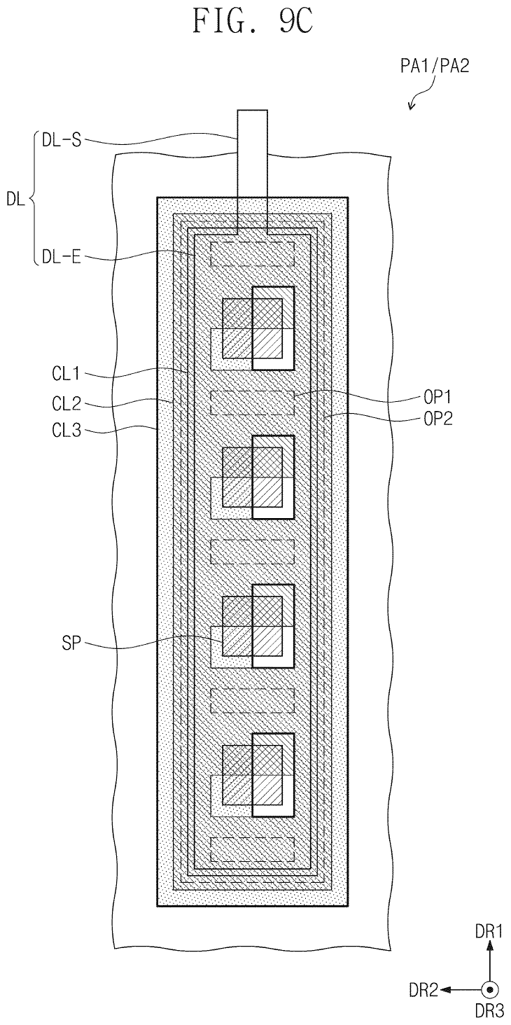

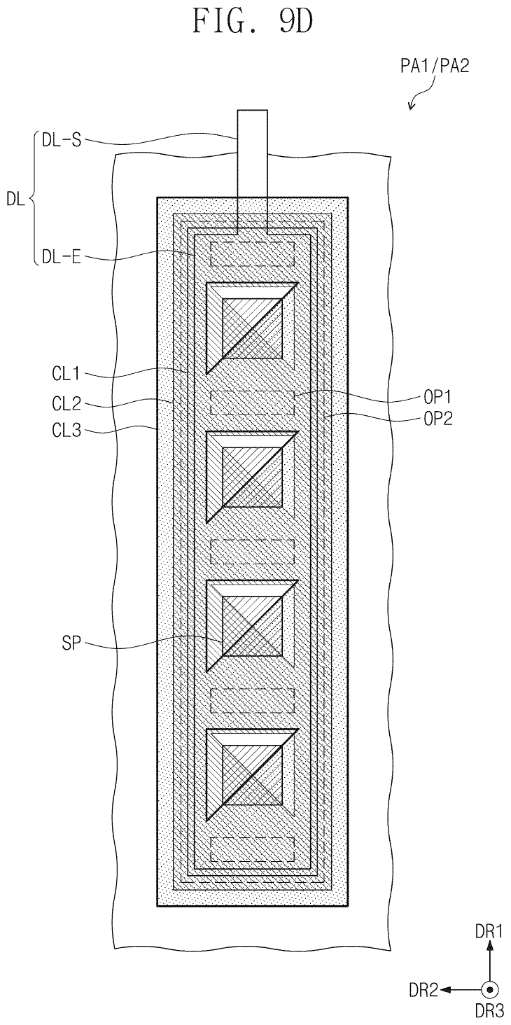

FIGS. 9A through 9D are plan views of the pad areas PA1 and PA2 according to some embodiments of the present disclosure. Hereinafter, redundant description of the same or substantially the same components as those described above with reference to FIGS. 7A to 7D may not be repeated.

Referring to FIG. 9A, four insulating patterns SP are illustrated as an example. The portion of the second conductive pattern CL2 may include a first edge or end, and the first edge or end may protrude in the second direction DR2 when viewed from above the plane (e.g., in a plan view). In some embodiments, the first edges or ends may not necessarily protrude in the same direction as each other in the second direction DR2. For example, on the four insulating patterns SP, the first edges or ends may protrude in different directions from one another in the second direction DR2. Similarly, a second edge or end facing in a direction opposite to that of the first edge or end in the second direction DR2 when viewed from above the plane (e.g., in a plan view) may not necessarily protrude in the same direction as those of the other second edges or ends in the second direction DR2, and the first edge or end and the second edge or end may overlap with each other on the upper surface of the insulating pattern SP.

Referring to FIG. 9B, the first edge or end and the second edge or end may have a curved shape. For example, the first edge or end and the second edge or end may have a semicircular shape. Accordingly, the first edge or end and the second edge or end may overlap with each other in an oval shape on the upper surface of the insulating pattern SP.

Referring to FIGS. 7A and 9C, the second conductive pattern CL2 may expose the second side surface SP-SL2 of the insulating pattern SP. For example, on the upper surface of the insulating pattern SP, the second conductive pattern CL2 may expose the entire second side surface SP-SL2 of the insulating pattern SP, and may expose a portion of the third side surface SP-SL3 and a portion of the fourth side surface SP-SL4. The third conductive pattern CL3 may expose the fourth side surface SP-SL4 of the insulating pattern SP. For example, on the upper surface of the insulating pattern SP, the third conductive pattern CL3 may expose the entire fourth side surface SP-SL4 of the insulating pattern SP, and may expose a portion of the first side surface SP-SL1 and a portion of the second side surface SP-SL2. In other words, the second conductive pattern CL2 may include a rectangular pattern that covers the entire first side surface SP-SL1 on the upper surface of the insulating pattern SP, and the third conductive pattern CL3 may include a rectangular pattern that covers the entire third side surface SP-SL3 on the upper surface of the insulating pattern SP. Accordingly, due to the second conductive pattern CL2 and the third conductive pattern CL3, the upper surface of the insulating pattern SP may include the fourth area R4 having a quadrangular shape where a portion of the second side surface SP-SL2 and a portion of the fourth side surface SP-SL4 are exposed.

Referring to FIGS. 7A and 9D, the second conductive pattern CL2 may expose the first side surface SP-SL1 and the fourth side surface SP-SL4 of the insulating pattern SP. The third conductive pattern CL3 may expose the first side surface SP-SL1 and the third side surface SP-SL3 of the insulating pattern SP. Accordingly, due to the second conductive pattern CL2 and the third conductive pattern CL3, the upper surface of the insulating pattern SP may include the fourth area R4 having a triangular shape where the first side surface SP-SL1 is exposed.

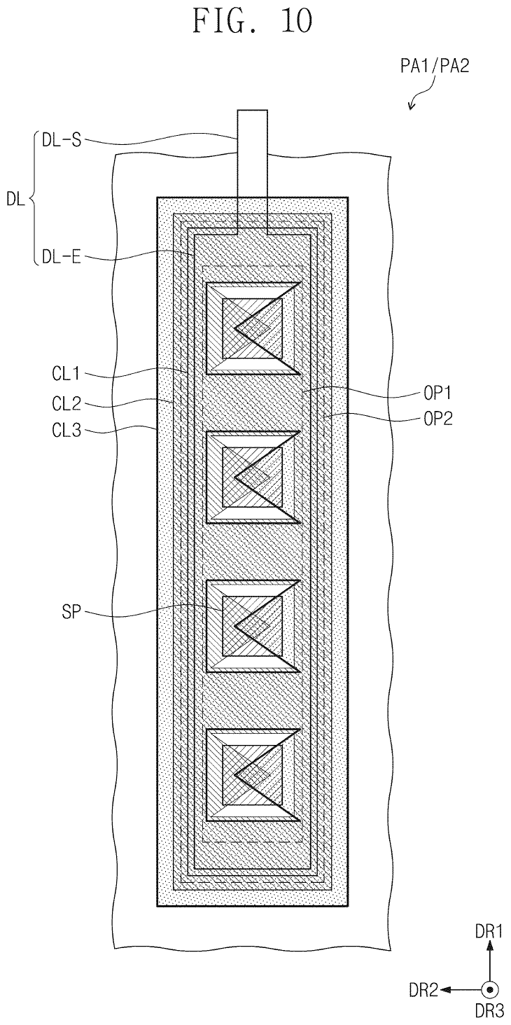

FIG. 10 is a plan view of the pad areas PA1 and PA2 according to an embodiment of the present disclosure. Hereinafter, redundant description of the same or substantially the same components as those described above with reference to FIGS. 7A to 7D may not be repeated.

In FIG. 10, one first contact hole OP1 disposed outside four insulating patterns SP when viewed from above the plane (e.g., in a plan view) is illustrated. In other words, a part of the side surfaces SP-SL1 to SP-SL4 (e.g., refer to FIG. 7A) of the insulating patterns SP may be exposed by the first contact hole OP1.

According to some embodiments of the present disclosure, an anisotropic conductive film for electrically connecting pad areas of electronic parts may be replaced with a low-viscosity adhesive layer. Because conductive balls may not applied, a short-circuit defect that may be caused by the conductive balls may be prevented or reduced, and because the low-viscosity adhesive layer may be used instead, a bonding may be performed at a lower bonding pressure. Furthermore, because the bonding pressure may be decreased, physical damage to the display panel or the electronic parts in the bonding process may be reduced.

According to some embodiments of the present disclosure, a conductive pattern of the signal pad may protrude toward the electronic part by the insulating pattern disposed on the signal pad of the display panel. A step of the conductive pattern may be formed on the insulating pattern of the signal pad, and thus, the signal pad may closely contact (e.g., may make close contact with) the bump of the electronic part. Accordingly, a bonding defect and an initial resistance may be reduced, which may lead to an improvement in a bonding reliability.

According to some embodiments of the present disclosure, because the conductive pattern may have a suitable shape exposing a portion of the upper surface of the insulating pattern, after the bonding process is completed, the insulating pattern may be more easily restored to the shape (e.g., the initial shape) before the bonding process.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base layer;
a pixel on the base layer;
a signal line electrically connected to the pixel;
a signal pad connected to the signal line; and
a plurality of insulating layers on the base layer,
wherein the signal pad comprises:
a first conductive pattern connected to an end portion of the signal line;
an insulating pattern on the first conductive pattern;
a second conductive pattern contacting the first conductive pattern, the second conductive pattern comprising a portion on a part of an area of an upper surface of the insulating pattern; and
a third conductive pattern on the first conductive pattern, the third conductive pattern comprising a portion overlapping with the portion of the second conductive pattern on the upper surface of the insulating pattern,
wherein a partial area of the upper surface of the insulating pattern is exposed from the second conductive pattern and the third conductive pattern, and
wherein the plurality of insulating layers comprises a first group of insulating layers between the end portion of the signal line and the first conductive pattern, and the end portion of the signal line and the first conductive pattern are connected to each other through a first contact hole defined in the first group of insulating layers.

2. The display device of claim 1, wherein the third conductive pattern further comprises a portion that does not overlap with the portion of the second conductive pattern on the upper surface of the insulating pattern.

3. The display device of claim 1, wherein the end portion of the signal line extends in a first direction in a plan view,
wherein a first area is an area of the upper surface of the insulating pattern where the second conductive pattern and the third conductive pattern overlap with each other,
wherein a second area is an area of the upper surface of the insulating pattern where the second conductive pattern is located and the third conductive pattern is not located,
wherein a third area is an area of the upper surface of the insulating pattern where the third conductive pattern is located and the second conductive pattern is not located, and
wherein the second area and the third area face each other in a second direction crossing the first direction.

4. The display device of claim 3, wherein a fourth area is the partial area of the upper surface of the insulating pattern that is exposed from the second conductive pattern and the third conductive pattern, and
wherein the fourth area comprises a fourth-first area and a fourth-second area spaced from each other in the first direction.

5. The display device of claim 3, wherein the insulating pattern further comprises a first side surface and a second side surface opposite to each other in the first direction, and a third side surface and a fourth side surface opposite to each other in the second direction, and
wherein the first side surface and the second side surface are exposed from the second conductive pattern and the third conductive pattern.

6. The display device of claim 5, wherein the third side surface contacts the second conductive pattern, and
wherein the fourth side surface contacts the third conductive pattern.

7. The display device of claim 3, wherein the portion of the second conductive pattern comprises a first edge,
wherein the portion of the third conductive pattern comprises a second edge facing in a direction opposite to that of the first edge in the second direction, and
wherein the first edge and the second edge overlap with each other on the upper surface of the insulating pattern.

8. The display device of claim 7, wherein the first edge and the second edge have a semicircular shape.

9. The display device of claim 1, wherein the end portion of the signal line extends in a first direction in a plan view,
wherein the insulating pattern further comprises a first side surface and a second side surface opposite to each other in the first direction, and a third side surface and a fourth side surface opposite to each other in a second direction crossing the first direction,
wherein the second side surface is exposed from the second conductive pattern, and
wherein the fourth side surface is exposed from the third conductive pattern.

10. The display device of claim 1, wherein the end portion of the signal line extends in a first direction in a plan view,
wherein the insulating pattern further comprises a first side surface and a second side surface opposite to each other in the first direction, and a third side surface and a fourth side surface opposite to each other in a second direction crossing the first direction,
wherein the first side surface and the fourth side surface are exposed from the second conductive pattern, and
wherein the first side surface and the third side surface are exposed from the third conductive pattern.

11. The display device of claim 1, further comprising:
an electronic part electrically connected to the signal pad,
wherein the electronic part comprises a bump electrically connected to the signal pad, and
wherein the second conductive pattern and the third conductive pattern located on the upper surface of the insulating pattern contacts the bump.

12. The display device of claim 1, wherein the end portion of the signal line extends in a first direction in a plan view,
wherein the first contact hole comprises a plurality of first contact holes,
wherein the plurality of first contact holes are located along the first direction,
wherein the insulating pattern comprises a plurality of insulating patterns, and
wherein the plurality of insulating patterns and the plurality of first contact holes are alternately located along the first direction.

13. The display device of claim 1, wherein the plurality of insulating layers further comprises a second group of insulating layers between the second conductive pattern and the third conductive pattern,
wherein a second contact hole penetrates the second group of insulating layers, and
wherein the second conductive pattern and the third conductive pattern are connected to each other through the second contact hole.

14. The display device of claim 13, wherein the first contact hole is located inside the second contact hole in a plan view.

15. The display device of claim 1, further comprising:
a thin film encapsulation layer on the pixel; and
a sensing electrode on the thin film encapsulation layer,
wherein the sensing electrode has a same stacked structure as that of the signal pad.

16. A display device comprising:
a base layer;
a pixel on the base layer;
a signal line electrically connected to the pixel;
a signal pad connected to the signal line; and
a plurality of insulating layers on the base layer,
wherein the signal pad comprises:
a first conductive pattern connected to an end portion of the signal line;
an insulating pattern on the first conductive pattern;
a second conductive pattern contacting the first conductive pattern, and overlapping with a portion of an upper surface of the insulating pattern, the second conductive pattern having a first opening defined therein to expose a partial area of the upper surface of the insulating pattern and a part of side surfaces of the insulating pattern; and
a third conductive pattern on the first conductive pattern, and overlapping with the portion of the upper surface of the insulating pattern, the third conductive pattern having a second opening defined therein to expose the partial area of the upper surface of the insulating pattern and a part of the side surfaces of the insulating pattern, and
wherein the plurality of insulating layers comprises a first group of insulating layers between the end portion of the signal line and the first conductive pattern, and the end portion of the signal line and the first conductive pattern are connected to each other through a first contact hole defined in the first group of insulating layers.

17. The display device of claim 16, wherein the end portion of the signal line extends in a first direction in a plan view,
wherein a first area is an area of the upper surface of the insulating pattern where the second conductive pattern and the third conductive pattern overlap with each other,
wherein a second area is an area of the upper surface of the insulating pattern where the second conductive pattern is located and the third conductive pattern is not located,
wherein a third area is an area of the upper surface of the insulating pattern where the third conductive pattern is located and the second conductive pattern is not located, and
wherein the second area and the third area face each other in a second direction crossing the first direction.

18. The display device of claim 17, wherein a fourth area is the partial area of the upper surface of the insulating pattern exposed from the second conductive pattern and the third conductive pattern, and
wherein the fourth area comprises a fourth-first area and a fourth-second area spaced from each other in the first direction.

19. The display device of claim 16, wherein the end portion of the signal line extends in a first direction in a plan view,
wherein the first contact hole comprises a plurality of first contact holes,
wherein the plurality of first contact holes are located along the first direction,
wherein the insulating pattern comprises a plurality of insulating patterns, and
wherein the plurality of insulating patterns and the plurality of first contact holes are alternately located along the first direction.

20. An electronic device comprising:
a display device; and
a housing accommodating the display device,
wherein the display device comprises:
a base layer;
a pixel on the base layer;
a signal line electrically connected to the pixel;
a signal pad connected to the signal line; and
a plurality of insulating layers on the base layer,
wherein the signal pad comprises:
a first conductive pattern connected to an end portion of the signal line;
an insulating pattern on the first conductive pattern;
a second conductive pattern contacting the first conductive pattern, the second conductive pattern comprising a portion located on a part of an area of an upper surface of the insulating pattern; and
a third conductive pattern on the first conductive pattern, the third conductive pattern comprising a portion overlapping with the portion of the second conductive pattern on the upper surface of the insulating pattern,
wherein a partial area of the upper surface of the insulating pattern is exposed from the second conductive pattern and the third conductive pattern, and
wherein the plurality of insulating layers comprises a first group of insulating layers between the end portion of the signal line and the first conductive pattern, and the end portion of the signal line and the first conductive pattern are connected to each other through a first contact hole defined in the first group of insulating layers.
